(19) United States
(12) Patent Application Publication
(10) Pub. No.: US 2006/0080054 A1
(43) Pub. Date: Apr. 13, 2006

(54) System and method for generating jitter analysis diagrams

(75) Inventors: Cheng-Shien Li, Tu-Cheng (TW); Shou-Kuo Hsu, Tu-Cheng (TW)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: HON HAI Precision Industry CO., LTD., Tu-Cheng City (TW)

(21) Appl. No.: 11/247,898

(22) Filed: Oct. 11, 2005

(30) Foreign Application Priority Data
Oct. 8, 2004 (CN) 200410051829.0

(51) Int. Cl. G01R 29/26

(52) U.S. Cl. 702/69

(57) ABSTRACT

A system and method for generating various jitter analysis diagrams and customized jitter analysis reports. The method includes the steps of: (a) obtaining a signal file; (b) determining a type of the signal file; (c) loading customized jitter analysis parameters; (d) generating a graphic function according to the customized jitter analysis parameters; (e) obtaining serial signals from the signal file; (f) separating transient signals and non-transient signals from the serial signals; (g) rebuilding an ideal clock based on the serial signals by means of performing a minimum deviation algorithm (MDA); (h) calculating and analyzing jitters of the serial signals according to the ideal clock by means of performing the MDA; (i) generating a jitter analysis diagram according to the graphic function; and (j) generating a jitter analysis report according the jitter analysis results.

### BACKGROUND OF THE INVENTION

1. Field of the Invention

The present invention relates to systems and methods for analyzing signals, and more particularly to a system and method for generating jitter analysis diagrams.

2. General Background

Jitter in serial data communication is a difference of data transition times relative to ideal bit clock active transition times. Jitter represents a deviation, typically in picoseconds, from the ideal. As data transfer rates of semiconductor devices increase and other high speed applications increase, the jitter component is believed to be of increasing significance too. For example, in video graphics chips, jitter can cause a flicker or jumping of the video image. Also, in serial data communication systems, jitter can cause errors. In order to understand the effects that jitter may have on semiconductor devices and data communication systems, measurements of jitter and other aspects of timing are critical during the prototyping stages and in production tests.

Generally, jitter has four major components, which are inter-symbol interference, cycle jitter, periodic jitter, and random jitter. As semiconductor devices and data communication systems continue to develop, analyzing the jitter components is valuable for the product designers and testers. For example, measuring the periodic jitter helps determine whether there is cross talk on a circuit. Analyzing the inter-symbol interference and the cycle jitter permits the cause of a bit error rate (BER) to be determined. Bit error test equipment allows a serial data pattern to be compared with a test pattern. Although the BER is determined, no information, such as a type of diagram or report, is provided about any of the jitter components of the BER. Because the relative proportions of the components are undetermined, the bit error test equipment provides only a slow method of estimating the BER.

Presently available measurement instruments do not separate jitters of signals, such as transient signals and non-transient signals. That is, when a measurement instrument measures a jitter value, it does not separate jitters of the transient signals and jitters of the non-transient signals. Furthermore, the presently available measurement instruments are typically used for analyzing measurement signals, and are not used for analyzing simulation signals. Therefore, formats of the measurement signals and the simulation signals are not compatible. Moreover, the presently available measurement instruments cannot generate various jitter analysis diagrams and customized jitter analysis reports.

What is needed, therefore, is an extensive and compatible computer system for generating various jitter analysis diagrams and customized reports by means of analyzing jitters of various signals.

Similarly, what is also needed is an extensive and compatible method for generating various jitter analysis diagrams and customized reports by means of analyzing jitters of various signals.

### SUMMARY

A computer system for generating jitter analysis diagrams in accordance with a preferred embodiment includes a jitter analysis diagram generating unit, a storage and a display unit. The jitter analysis diagram generating unit is used for obtaining a serial signals from a signal file, calculating and analyzing jitters of the serial signals, generating various graphic functions, generating various jitter analysis diagrams according to the graphic functions, and generating jitter analysis reports according to the jitter analysis results. The signal file may be a type of signal measurement result file, or a signal simulation result file; the jitter analysis diagram may be an eye-diagram, a bathtub curve, a histogram, a time domain diagram, or a frequency domain diagram. The storage is used for storing signal files and source codes of applications executable by the jitter analysis diagram generating unit. The display unit is used for displaying the jitter analysis diagrams and the jitter analysis reports.

The jitter analysis diagram generating unit includes a jitter analyzing module, a diagram generating module, and a report generating module. The jitter analyzing module is used for identifying a type of the signal file, obtaining serial signals from the signal file, rebuilding ideal clocks based on the serial signals, calculating and analyzing jitters of the signal file according to the ideal clocks, and generating jitter analysis results. The diagram generating module is used for generating a jitter analysis diagram according to the corresponding graphic function. The report generating module is used for generating the jitter analysis reports according to the jitter analysis results.

Another preferred embodiment provides a method for generating a jitter analysis diagram by utilizing the above system. The method includes the steps of: (a) obtaining a signal file; (b) determining a type of the signal file; (c) loading customized jitter analysis parameters; (d) generating a graphic function according to the customized jitter analysis parameters; (e) obtaining serial signals from the signal file; (f) separating transient signals and non-transient signals from the serial signals; (g) rebuilding an ideal clock based on the serial signals by means of performing a minimum deviation algorithm (MDA); (h) calculating and analyzing jitters of the serial signals according to the ideal clock by means of performing the MDA; (i) generating a jitter analysis diagram according to the graphic functions; and (j) generating jitter analysis a report according the jitter analysis results.

The graphic functions is any of an eye-diagram function, a bathtub curve function, a histogram function, a time domain diagram function, and a frequency domain diagram function. The eye-diagram function is used for generating a transient eye-diagram in one unit interval (UI) by means of combining all jitters of the transient signals in the UI, and generating a non-transient eye-diagram in one UI by means of combining all jitters of the non-transient signals in the UI. The bathtub curve function is used for generating a bathtub curve showing the relationship between different bit error rates in one UI, by means of calculating a logarithm of a complement of a multiple of each standard deviation of a Gaussian distribution function. The histogram function is used for generating a histogram by means of dividing various jitter frequency and jitter numbers in intervals of the jitter distribution into the same UI. The time domain diagram function is used for generating a time domain diagram by means of calculating jitter periods in various times of the serial signals. The frequency domain diagram function is used for generating a frequency domain diagram by means of transforming the jitter period to the jitter frequency by performing a Fourier transform.

Other advantages and novel features of the embodiments will be drawn from the following detailed description with reference to the attached drawings, in which:

### BRIEF DESCRIPTION OF THE DRAWINGS

FIG. 1 is a schematic diagram of a computer system for generating jitter analysis diagrams according to a preferred embodiment of the present invention;

FIG. 2 is a diagram illustrating main data interchanges in the system of FIG. 1;

FIG. 3 is a schematic diagram of an exemplary method for generating an eye-diagram according to the present invention;

FIG. 4 is a schematic diagram of an exemplary method for generating a bathtub curve according to the present invention;

FIG. 5 is a schematic diagram of an exemplary method for generating a histogram according to the present invention;

FIG. 6 includes schematic diagrams of exemplary methods for generating a time domain diagram and a frequency domain diagram according to the present invention; and

FIG. 7 is a flowchart of a preferred method for generating a jitter analysis diagram by implementing the system of FIG. 1.

### DETAILED DESCRIPTION OF THE EMBODIMENTS

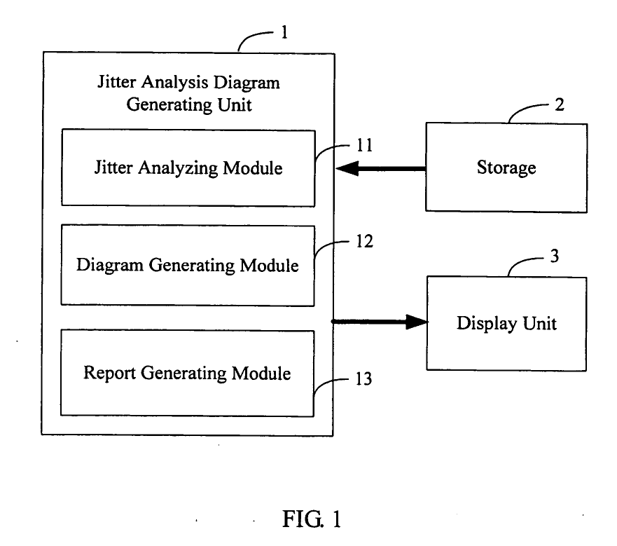

FIG. 1 is a schematic diagram of a computer system for generating jitter analysis diagrams (hereinafter, “the system”) according to a preferred embodiment of the present invention. The system includes a jitter analysis diagram generating unit 1, a storage 2, and a display unit 3. The jitter analysis diagram generating unit 1 includes a jitter analyzing module 11, a diagram generating module 12, and a report generating module 13. The jitter analyzing module 11 is used for obtaining signal files from the storage 2, identifying a type of each signal file, obtaining serial signals from the signal files, rebuilding ideal clocks based on the serial signals, calculating and analyzing jitters of the signal files according to the ideal clocks, and generating jitter analysis results. Each signal file may be a type of signal measurement result file designated as *.csv, or a signal simulation result file designated as *.tr or *.cur. The diagram generating module 12 is used for generating various graphic functions, and generating corresponding jitter analysis diagrams according to the graphic functions. The jitter analysis diagram is any of an eye-diagram, a bathtub curve, a histogram, a time domain diagram, and a frequency domain diagram. The report generating module 13 is used for generating a jitter analysis report according to corresponding jitter analysis results. The storage 2 is used for storing the signal files and source codes of applications executable by the jitter analysis diagram generating unit 1. The display unit 3 is used for receiving the jitter analysis diagrams from the diagram generating module 12 and the jitter analysis reports from the report generating module 13, and displaying the jitter analysis diagrams and the jitter analysis reports.

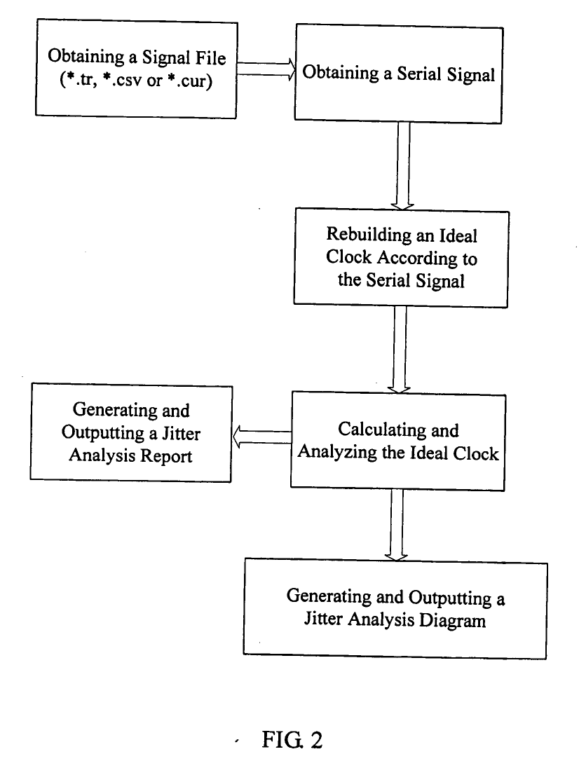

FIG. 2 illustrating main data interchanges in the system. Firstly, the jitter analyzing module 11 obtains a signal file from the storage 2, and identifies a type of the signal file, which may be a signal measurement result file (*.csv) or a signal simulation result file (*.tr or *.cur). Secondly, the jitter analyzing module 11 obtains a serial signal from the signal file, and rebuilds an ideal clock based on the serial signal by means of utilizing a minimum deviation algorithm (MDA), which is a clock recovery algorithm. Finally, the jitter analyzing module 11 calculates and analyzes jitters of the signal file according to the ideal clock by means of utilizing the MDA. The diagram generating module 12 generates a jitter analysis diagram according to a corresponding graphic function, and outputs the jitter analysis diagram to the display unit 3. Simultaneously, the report generating module 13 generates a jitter analysis report according to the jitter analysis results, and outputs the jitter analysis report to the display unit 3.

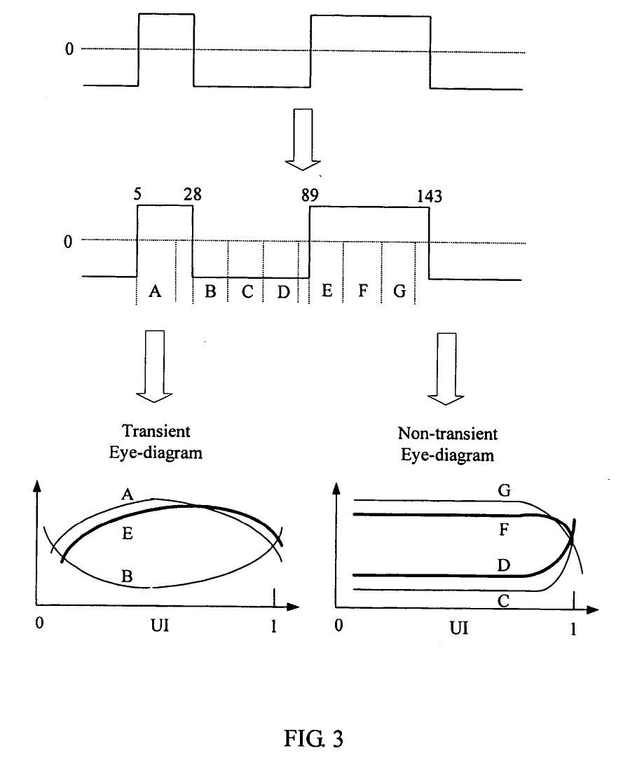

FIG. 3 is a schematic diagram of an exemplary method for generating an eye-diagram. The jitter analyzing module 11 obtains serial signals from a signal file, and then separates transient signals and non-transient signals from the serial signals. Then the diagram generating module 12 generates an eye-diagram of the transient signals and an eye-diagram of the non-transient signals in one unit interval (UI). The transient signals are serial signals whose current data is different from the previous data. For example, a serial signal “01” is a kind of transient signal. The serial signal “10” is another kind of transient signal. The non-transient signals are serial signals whose current data is the same as the previous data. For example, serial signals “00” and “11” are both non-transient signals.

In the preferred embodiment of the present invention, the jitter analyzing module 11 rebuilds an ideal clock based on the serial signals by performing the MDA described above, and divides the serial signals into transient signals and non-transient signals. Referring to FIG. 3, it is assumed: the first data change point is 5, the second data change point is 28, the third data change point is 89, the fourth data change point is 143, and the bit-width of the ideal clock is 20. The jitter analyzing module 11 divides the first interval into one UI (symbolically depicted as “A”), divides the second interval into three UIs (symbolically depicted as “B,” “C,” and “D”), and divides the third interval into three UIs (symbolically depicted as “E,” “F,” and “G”). According to the definitions of transient signals and non-transient signals, the serial signals “A,” “B,” and “E” are transient signals, and the serial signals “C,” “D,” “F,” and “G” are non-transient signals. The jitter analyzing module 11 combines jitters of the transient signals “A,” “B,” and “E,” and the diagram generating module 12 generates a transient eye-diagram in one UI. Similarly, the jitter analyzing module 11 combines jitters of the non-transient signals “C,” “D,” “F,” and “G,” and the diagram generating module 12 generates a non-transient eye-diagram in the same UI.

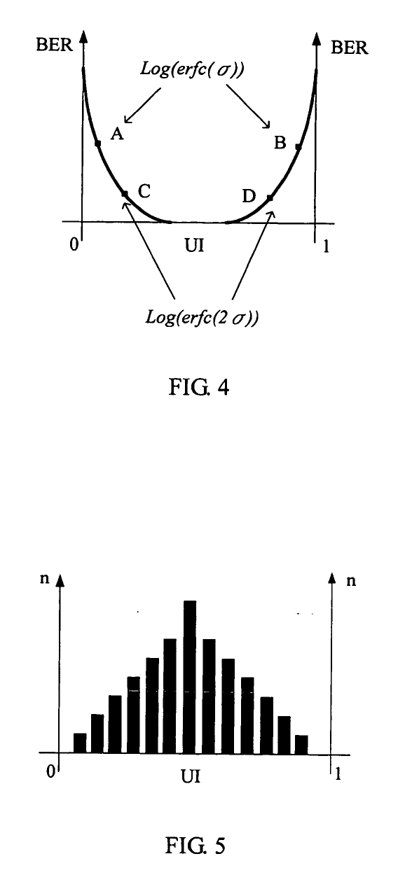

FIG. 4 is a schematic diagram of an exemplary method for generating a bathtub curve. The bathtub curve shows the effects of different bit error rates (BERs) on jitters of the serial signals. In general statistics theory, jitter calculation is performed according to a Gaussian distribution function. The BER corresponds to a complement error function (symbolically depicted as “erfc”) of the Gaussian distribution, and relates to a multiple of a standard deviation (symbolically depicted as “σ”) of the Gaussian distribution function. In the preferred embodiment of the present invention, the jitter analyzing module 11 firstly calculates a complement of each multiple ofσ, and then calculates a logarithm of the complement of the multiple ofσ. Referring to FIG. 4, the values of dot “A” and dot “B” are respectively equal to Log(erfc(σ)), and the values of dot “C” and dot “D” are respectively equal to Log(erfc(2σ)). The diagram generating module 12 draws a diagram showing the relationship between different BERs and the UI according to the values of dots “A,” “B,” “C,” and “D,” and obtains a bathtub curve.

FIG. 5 is a schematic diagram of an exemplary method for generating a histogram. The histogram is a statistical diagram, which shows distribution characters for the effects of remainder signals in jitters of the serial signals. In the preferred embodiment of the present invention, the jitter analyzing module 11 divides jitter distribution intervals into the same length of UI. Then, the diagram generating module 12 draws a histogram according to the divided jitter frequency and jitter numbers in intervals of the jitter distribution into a same UI. From the histogram, users can analyze the jitter frequency and jitter numbers of the serial signals in one UI.

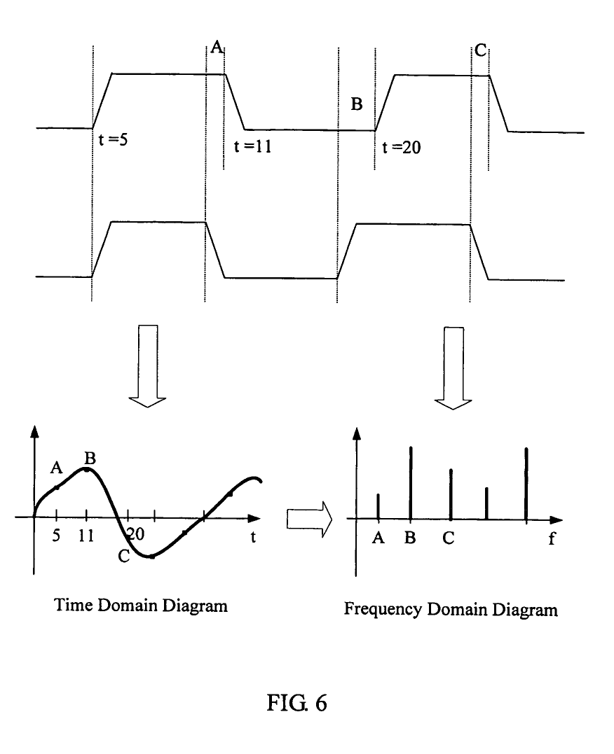

FIG. 6 includes schematic diagrams of exemplary methods for generating a time domain diagram and a frequency domain diagram. The time domain diagram shows a relationship of jitter periods in various times of serial signals. The frequency domain diagram shows a relationship of jitter frequency in different times of the serial signals. In the preferred embodiment of the present invention, it is assumed that the start-bit of a first signal is 5 whose jitter corresponds to “A;” the start-bit of a second signal is 11 whose jitter corresponds to “B;” and the start-bit of a third signal is 20 whose jitter corresponds to “C.” The diagram generating module 12 draws the time domain diagram of the jitters according to the start-bits of “A,” “B” and “C.” Similarly, the jitter analyzing module 11 transforms the jitter period to the jitter frequency by means of a Fourier transform. Then the diagram generating module 12 draws the frequency domain diagram of the jitter according the jitter frequency. From the time domain diagram or the frequency domain diagram, the users can analyze whether the jitters are logical according to jitter trends in the diagram.

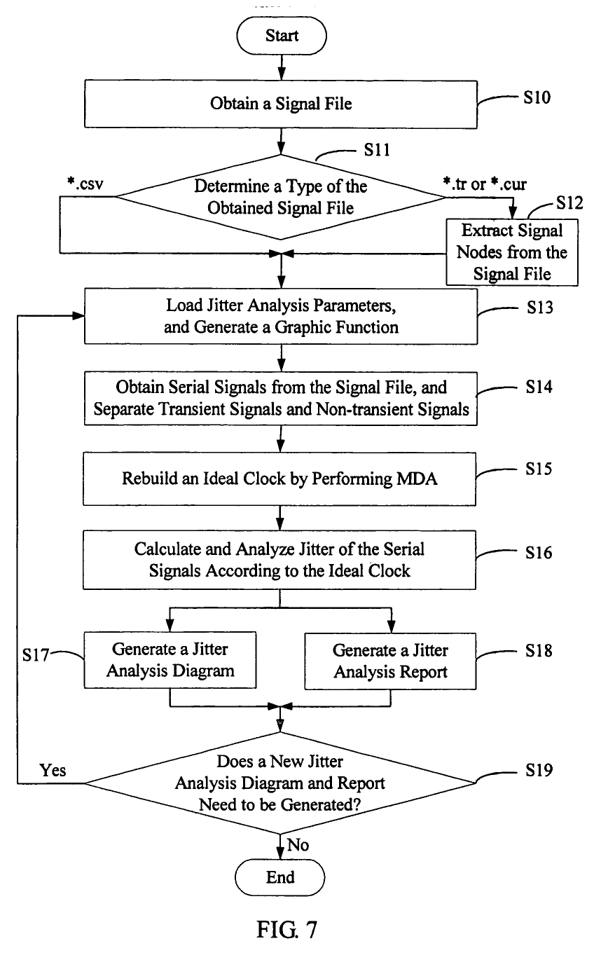

FIG. 7 is a flowchart of a preferred method for generating a jitter analysis diagram by implementing the system. In step S10, the jitter analyzing module 11 obtains a signal file from the storage 2. In step S11, the jitter analyzing module 11 determines a type of the obtained signal file. If the signal file is a signal measurement result file whose file format is *.csv, the procedure goes directly to step S13 described below. Otherwise, if the signal file is a signal simulation result file whose file format is *.tr or *.cur, in step S12, the jitter analyzing module 11 selectively extracts signal nodes from the obtained signal file. The signal nodes contain data generated during the simulation process. In step S13, the jitter analyzing module 11 loads customized jitter analysis parameters, and the diagram generating module 12 generates a graphic function for drawing the jitter analysis diagram. The parameters may include a period, a frequency, a phase, and a bandwidth of signals. The graphic function may be an eye-diagram function, a bathtub curve function, a histogram function, a time domain diagram function, or a frequency domain diagram function. In step S14, the jitter analyzing module 11 obtains serial signals from the signal file, and separates transient signals and non-transient signals from the serial signals by means of utilizing the method described above in relation to FIG. 3. In step S15, the jitter analyzing module 11 rebuilds an ideal clock based on the serial signals by performing the MDA described above. In step S16, the jitter analyzing module 11 calculates and analyzes the serial signals according to the phase and period of the ideal clock by means of utilizing the MDA. In step S17, the diagram generating module 12 generates a jitter analysis diagram by performing the graphic function. The jitter analysis diagram may be an eye-diagram including a transient eye-diagram and a non-transient eye-diagram, a bathtub curve, a histogram, a time domain diagram, or a frequency domain diagram. In step S18, the report generating module generates a customized jitter analysis report according to the jitter analysis results. In step S19, the jitter analyzing module 11 determines whether a new jitter analysis diagram or a report needs to be generated. If a new jitter analysis diagram or a report needs to be generated, the procedure returns to the step S13 described above. Otherwise, if there is no need to generate a new jitter analysis diagram or report, the procedure is finished.

Although the present invention has been specifically described on the basis of a preferred embodiment and preferred method, the invention is not to be construed as being limited thereto. Various changes or modifications may be made to the embodiment and method without departing from the scope and spirit of the invention.

We claim:

1. A computer system for generating jitter analysis diagrams, the system comprising:
a jitter analysis diagram generating unit for obtaining serial signals from a signal file, calculating and analyzing jitters of the serial signals, generating various graphic functions, generating various jitter analysis diagrams according to the graphic functions, and generating jitter analysis reports according to corresponding jitter analysis results; and
a storage for storing the signal file and source codes of applications executable by the jitter analysis diagram generating unit.

2. The system according to claim 1, further comprising a display unit for displaying the jitter analysis diagrams and the jitter analysis reports.

3. The system according to claim 1, wherein the jitter analysis diagram generating unit comprises a jitter analyzing module for identifying a type of the signal file, obtaining the serial signals from the signal file, rebuilding ideal clocks based on the serial signals, calculating and analyzing jitters of the serial signals according to the ideal clocks, and generating the jitter analysis results.

4. The system according to claim 1, wherein the jitter analysis diagram generating unit comprises a diagram generating module for generating various jitter analysis diagrams according to the corresponding graphic functions.

5. The system according to claim 1, wherein the jitter analysis diagram generating unit comprises a report generating module for generating the jitter analysis reports according to the jitter analysis results.

6. The system according to claim 1, wherein the signal file is any one of a type of signal measurement result file and a signal simulation result file.

7. The system according to claim 1, wherein the jitter analysis diagrams include an eye-diagram, a bathtub curve, a histogram, a time domain diagram, and a frequency domain diagram.

8. A computerized method for generating a jitter analysis diagram, the method comprising the steps of:
obtaining a signal file;
loading customized jitter analysis parameters;
generating a graphic function according to the customized jitter analysis parameters;
obtaining serial signals from the signal file;
rebuilding an ideal clock based on the serial signals;
calculating and analyzing jitters of the serial signals according to the ideal clock; and
generating a jitter analysis diagram according to the graphic function.

9. The method according to claim 8, further comprising the steps of:
determining a type of the signal file; and
loading the customized jitter analysis parameters directly, if the signal file is a signal measurement result file; or
extracting signal nodes from the signal file, and loading the customized jitter analysis parameters, if the signal file is a signal simulation result file.

10. The method according to claim 8, further comprising the step of separating transient signals and non-transients signals from the serial signals.

11. The method according to claim 8, further comprising the step of generating a jitter analysis report according the jitter analysis results.

12. The method according to claim 8, wherein the jitter analysis parameters include a period, a frequency, a phase, and a bandwidth of the serial signals.

13. The method according to claim 8, wherein the graphic function is any of an eye-diagram function, a bathtub curve function, a histogram function, a time domain diagram function, and a frequency domain diagram function.

14. The method according to claim 13, wherein the eye-diagram function is used for generating a transient eye-diagram in one unit interval (UI) by means of combining all jitters of the transient signals in the UI.

15. The method according to claim 13, wherein the eye-diagram function is used for generating a non-transient eye-diagram in one UI by means of combining all jitters of the non-transient signals in the UI.

16. The method according to claim 13, wherein the bathtub curve function is used for generating a bathtub curve showing the relationship between different bit error rates in one UI, by means of calculating a logarithm of a complement of a multiple of each standard deviation of a Gaussian distribution function.

17. The method according to claim 13, wherein the histogram function is used for generating a histogram by means of dividing various jitter frequency and jitter numbers in intervals of the jitter distribution into a same UI.

18. The method according to claim 13, wherein the time domain diagram function is used for generating a time domain diagram by means of calculating jitter periods in various times of the serial signals.

19. The method according to claim 13, wherein the frequency domain diagram function is used for generating a frequency domain diagram by means of transforming the jitter period to the jitter frequency by performing a Fourier transform.

20. A method for analyzing jitter of signals, comprising the steps of:
obtaining a signal file;
identifying transient signals and non-transient signals from said signal file;
calculating jitter of said signal file for said transient signals and non-transient signals respectively; and
generating a jitter analysis result according to said calculated jitter.
